(19) United States
(12) Patent Application Publication
(10) Pub. No.: US 2009/0045478 A1
(43) Pub. Date: Feb. 19, 2009

(54) CMOS image sensor package structure

(76) Inventor: Yeh Hsin Hui, Hsinchu City (TW)

Correspondence Address: REED SMITH LLP, Suite 1400, 3110 Fairview Park Drive, Falls Church, VA, 22042, US

(21) Appl. No.: 11/987,223

(22) Filed: Nov. 28, 2007

(30) Foreign Application Priority Data
Aug. 17, 2007 (TW) 096130410

(51) Int. Cl. H01L 31/0203

(52) U.S. Cl. 257/434; 257/E31.11

(57) ABSTRACT

The present invention provides a complementary metal oxide semiconductor (CMOS) sensor package structure that includes a carrier substrate having a top surface and a bottom surface; a metal layer placed on the top surface of the carrier substrate and exposed a portion of the top surface of the metal layer; the plurality of CMOS chips having an active surface thereon formed on a portion of the top surface of the metal layer, and being exposed a portion of the active surface; a plurality of connecting elements formed on the bottom surface of the plurality of CMOS chips and a portion of the top surface of the metal layer; a molding material covers a portion of the top surface of the carrier substrate, a plurality of the connecting elements and the bottom surface of each of the plurality of CMOS chips and a plurality of the conductive elements formed on the top of the plurality of connecting elements on the metal layer.

### BACKGROUND OF THE INVENTION

1. Field of the Invention

The present invention is a semiconductor package structure and more particularly is a CMOS image sensor package structure.

2. Description of the Prior Art

The development of the semiconductor technology is extremely faster. The semiconductor dice is trend to become smaller and smaller but the function of the semiconductor dice is more and more powerful. In other word, there are more input/output pads needed in a small region of the semiconductor dice and the density of the pins is higher than before. Therefore, the package of the semiconductor dice is more and more difficult and the liability is reduced. The main purpose of the semiconductor package is to protect the dice from damaging by external force.

However, most of the package technology is to cut the wafer dice to several small and single dices first and then package and test each of the dices. Besides, the wafer level package (WLP) is to package the dices before cutting the wafer into a single dice. The advantage of the wafer level package is short manufacture cycle, low cost, under-fill unneeded and so on.

Digital image technology is widely used in image photographic device, such as digital camera, image scanner and so on. Most of the image photographic devices are used Complementary Metal-Oxide Semiconductor (CMOS) image sensor to be the element for image catching. CMOS image sensor includes at least one dice disposed therein. The image signal is transferred to the digital processor by a plurality of the array sensor elements of the sensor region of the chip. The image is transferred from analog signal to be digital signal.

Because the sensor region of the CMOS image sensor element is very sensitive to dust, the dust would reduce the quality of the test element. In order to achieve the purpose described above, there is a transparent material, such as glass, formed on a plurality of the sensor elements of the sensor region of the dice to protect the sensor elements and increase the ability of focus.

Now, referring to FIG. 1, it is a package structure of the CMOS image sensor device formed by wafer level package (WLP) in prior art. The package structure is to form a CMOS image sensor device on the isolated board 100 and form a mini-lens 140 on the sensor region of the CMOS image sensor. Then, a protective layer 150 is formed on the array of the mini-lens 140.

Obviously, in prior art, the package process of the CMOS image sensor device is more complicated and needed to be done by one layer after another. The time for the package process is wasted and the CMOS image sensor is easy to be polluted during the period of the package process. Therefore, a new package process and method for CMOS sensor is disclosed herein to reduce the time for the package process and enhance the reliability of the CMOS sensor.

### SUMMARY OF THE INVENTION

According to the problems described above, the main purpose of the present invention is to provide a package structure for CMOS image sensor device to reduce the package process time and cost.

Another purpose of the present invention is to provide a Complementary Metal-Oxide Semiconductor (CMOS) image sensor package structure to increase the liability of the device.

According to the purpose described above, a package structure of CMOS image sensor device includes a carrier substrate, a patterned metal layer, a CMOS image sensor dice, a plurality of connecting elements, a molding material and a plurality of conductive elements. The carrier substrate has a top surface and a bottom surface and the patterned metal layer is disposed and exposed on the top surface of the carrier substrate. The CMOS image sensor dice includes an active surface, a plurality of CMOS image sensor elements and a plurality of pads. The CMOS image sensor elements are disposed on the active surface and the pads are disposed around the active surface and electrically connected to a portion of the patterned metal layers. The connecting elements are disposed on a portion of the patterned metal layer and formed the electrical connection. The molding material covers the top surface of the carrier substrate, the connecting elements and the CMOS image sensor dice. The conductive elements are formed on the connecting elements.

The detailed description of the present invention will be discussed in the following embodiments, which are not intended to limit the scope of the present invention, but can be adapted for other applications. While drawings are illustrated in details, it is appreciated that the quantity of the disclosed elements may be greater or less than that disclosed, except expressly restricting the amount of the elements.

### BRIEF DESCRIPTION OF THE DRAWINGS

FIG. 1 is sectional view showing that a package structure is formed by wafer level package (WLP) in prior art.

FIG. 2 is a view showing that a plurality of patterned metal layer formed on the carrier substrate.

FIG. 3 is a sectional view showing that a plurality of Complementary Metal-Oxide Semiconductor (CMOS) image sensor dices are stuck on a plurality of the patterning metal layer.

FIG. 4 is a sectional view showing that the connecting elements are formed on the structure in FIG. 3.

FIG. 5 is a sectional view showing the structure in FIG. 4 covered by a molding material.

FIG. 6 is a view showing that the conductive elements are formed on the connecting element.

FIG. 7 is another embodiment disclosed in the present invention.

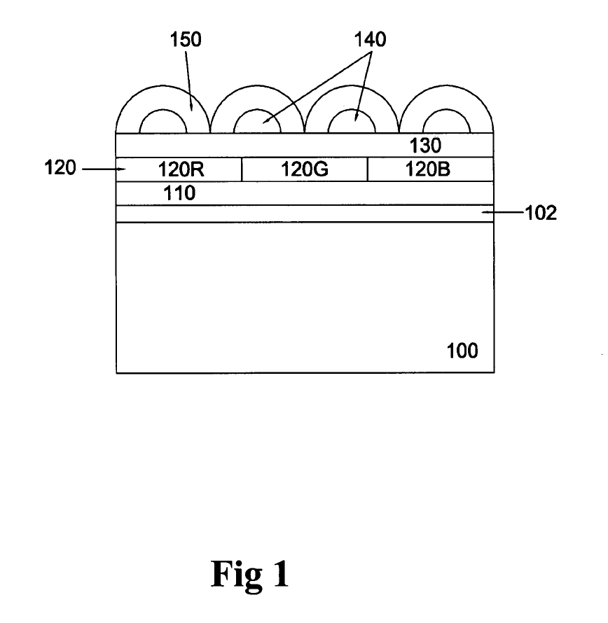

### DESCRIPTION OF THE PREFERRED EMBODIMENT

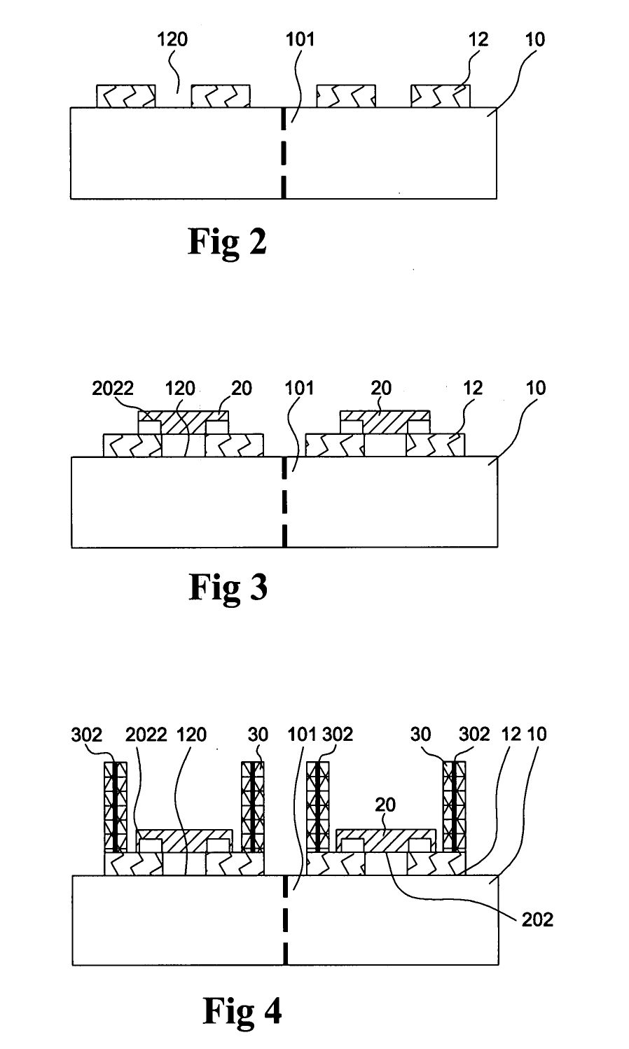

The present invention is a Complementary Metal-Oxide Semiconductor (CMOS) image sensor package structure. Therefore, the present invention is to package the CMOS image sensor chip after the CMOS image sensor is manufactured and cut. However, in order to describe clearly, the CMOS image sensor chip in the present invention is formed by a plurality of sensor elements on an active surface and there are a plurality of pads disposed around the sensor elements. FIGS. 2 to FIG. 7 are sectional views and views showing that the CMOS image sensor package structure and process steps in the present invention.

Please referring to FIG. 2, it is a sectional view showing that a plurality of pattering metal layer formed on the carrier substrate. First of all, a carrier substrate 10 is provided herein and includes a top surface and a bottom surface. In the embodiment of the present invention, the carrier substrate 10 is a transparent material, such as glass or optical glass. As shown in FIG. 2, the methods for a plurality of metal layers 12 formed on the carrier substrate 10 are: forming a metal layer 12 on the carrier substrate 10; coating a photoresist layer on the metal layer and the photoresist layer is exposed and developed by a patterning mask; executing a etching step to remove a portion of the metal layer; and removing the patterned photoresist layer and forming a plurality of metal layers 12 with the same pattern.

In addition, the step of forming a plurality of the patterned metal layers on the carrier substrate includes: coating the photoresist layer on the carrier substrate 10; forming a patterned concave or channel on the photoresist layer after exposing and developing by a patterning mask; filling the metal material in the concave or channel and removing the photoresist layer to form a patterned metal layer 12 on the carrier substrate 10. The metal material in the present invention is formed by evaporating process or sputtering process. But in the preferred embodiment, the metal material is formed by plating.

In addition, the dot lines 101 of the carrier substrate 10 are sawing street. The dot lines 101 are formed on the carrier substrate 10 when the semiconductor package is processed or the dot lines 101 doesn't exist at the beginning of the semiconductor package. The purpose of the dot line 101 is used to be the reference line for cutting the carrier substrate 10 after the package process is done to form a plurality of single packaged elements.

Now please referring to FIG. 3, it is a sectional view showing that a plurality of Complementary Metal-Oxide Semiconductor (CMOS) image sensor dices 20 are attached on a plurality of the patterned metal layer 12. The active surface 202 of the CMOS image sensor dice 20 includes a plurality of array sensor elements (not shown) and a plurality of pads 2022 disposed around the sensor elements. As shown in FIG. 3, a plurality of the pads 2022 in each of the CMOS image sensor dices 20 are faced to the top surface of the patterned metal layer 12 by flip chip technology, and a plurality of the pads 2022 and a portion of the top surface of the patterned metal layer 12 are electrically connected. Therefore, each of a plurality of array sensor elements on the CMOS image sensor dices 20 is able to sensor the object through the transparent carrier board 10 according to the flip chip technology. A plurality of the pads 2022 and a portion of the top surface of the patterned metal layer 12 are electrically connected by conductive glue (now shown), such as solder paste.

Now please referring to FIG. 4, it is a sectional view showing that the connecting elements are formed on the structure in FIG. 3. As shown in FIG. 4, a plurality of connecting elements 30 are formed on the exposed portion of the top surface of the patterned metal layer 12 and closed to each of the CMOS image sensor dices 20. The height in each of the connecting elements is equal and higher than the thick of the CMOS image sensor dices 20. In the present embodiment, the connecting elements 30 are the structures with golden finger and used to cover a plurality of the metal lines 302 corresponding to the patterned metal layer 12 by the isolated material (such as plastic) or the ceramic material. Then, the connecting elements 30 are electrically connected to the patterned metal layer 12 of the carrier substrate 10 by the molding material (not shown), such as solder paste.

As the package process shown FIG. 2 and FIG. 3, the molding material is used to be the connecting material. Therefore, in the package process, the molding material can be used to coat on the patterned metal layer 12. The molding material can be coated on the pads 2022 of the CMOS image sensor dices 20 and the end point of the connecting element 30. There is no limitation in the present invention.

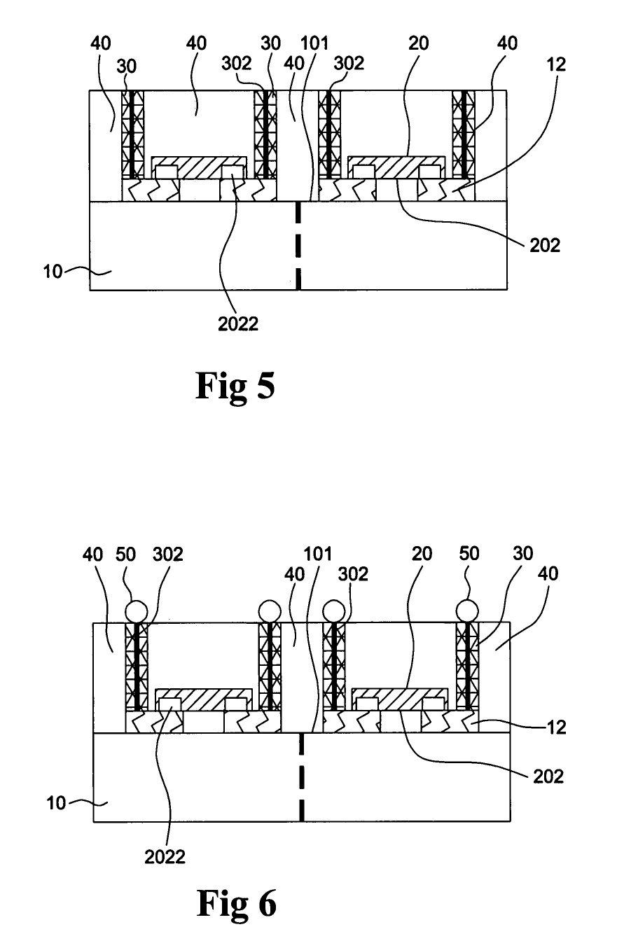

Now, as shown in FIG. 5, it is a sectional view showing the structure in FIG. 4 covered by a molding material 40. After electrically connecting the connecting elements 30 with the patterned metal layer 12, the molding process is used to form a molding material 40 to cover the CMOS image sensor dice 20, the connecting elements 30 and the patterned metal layer 12. And then, a portion of the molding material 40 is removed to expose the connecting element 30. For example, as the connecting material 30 is a golden finger, a portion of the molding material 40 is removed to expose the end point of the metal line 302. Besides, before the molding process, there is a protective layer (not shown), such as adhesive tape, used to cover the connecting elements 30, such as the end point of the metal line 302 and the molding material is injected until the height is equal to the height of the connecting element 30. Then the degumming process is used to expose the connecting elements 30. However, in the embodiment of the present invention, the molding material is epoxy or colloid.

Please referring to FIG. 6, it is a view showing that the conductive elements are formed on the connecting element 30 (such as metal line 302). In this embodiment, the package technology, such as solder ball, in prior art is used. A plurality of conductive elements 50 are formed on the top of each of the exposed connecting elements 30. The conductive elements are used to be the electrical connecting point for the external of the package object. It should be noted that the conductive element can be solder ball or solder bump.

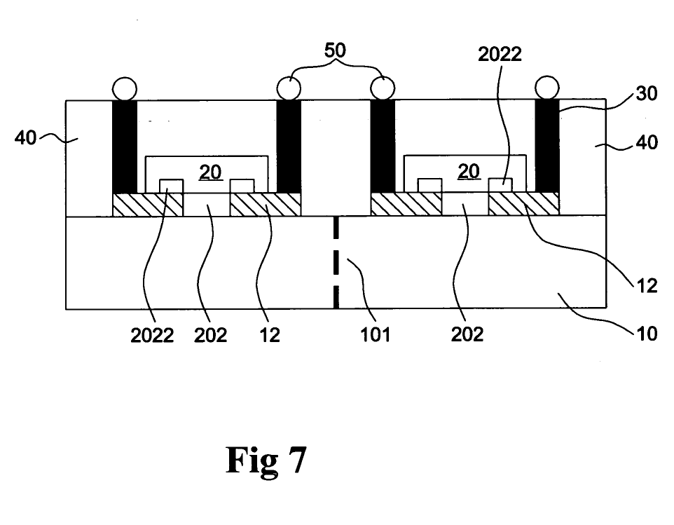

Besides, as shown in FIG. 7, there is another embodiment disclosed in the present invention. In this embodiment, the molding process is used to form a molding material to cover the CMOS image sensor dices 20 and a portion of the patterned metal layer 12 after the CMOS image sensor dices 20 and the patterned metal layer 12 of the carrier substrate 10 are electrically connected. Then, after the alignment process was done, the molding material 40 on a portion of the patterned metal layer 12 is removed by etching process, such as dry etching or reactive ion etching (RIE), to form a plurality of holes and expose a portion of the patterned metal layer 12. After the etching process, the electroplate method is used to fill the conductive materials into the holes to form a plurality of connecting elements 30. Then, the conductive elements 50 are formed on the connecting elements 30 to finish the package process of the CMOS image sensor dice 20. Similarly, the conductive elements 30 can be solder balls or solder bumps.

After accomplishing the steps described in the previous paragraph and shown in FIG. 6 and FIG. 7, the die sawing process is used to cut the carrier substrate 10 according to the position of the dot line 101 to form a plurality of the packaged CMOS image sensor chips. Obviously, as the embodiment shown in the present invention, the step of forming a plurality of the patterned metal layer 12 and the step of accomplishing the CMOS image sensor chip can be separated to efficiently reduce the package process time. In addition, as the process steps shown in the present invention, there are five surfaces in each of the CMOS image sensor dice 20 and all of them are covered by the molding material 40. Therefore, the liability of the CMOS image sensor dice 20 can be enhanced.

When the CMOS image sensor dice 20 is packaged to from the CMOS image sensor device, the CMOS image sensor device is electrically connected to the circuit board (not shown) by a plurality of the conductive elements 50. The circuit board is used to electrically connect to other controlled devices to drive the CMOS image sensor device of the present invention to catch the image.

Especially, when the CMOS image sensor device is connected to the flexible circuit, it can be used to be any portable digital image device, such as digital camera, personal digital assistant (PDA), mobile device with taking photo function (such as mobile phone) and so on, to increase the utility of the CMOS image sensor device.

Although specific embodiments have been illustrated and described, it will be appreciated by those skilled in the art that various modifications may be made without departing from the scope of the present invention, which is intended to be limited solely by the appended claims.

What is claimed is:

1. A complementary metal oxide semiconductor (CMOS) image sensor package structure comprising:
a carrier substrate having a top surface and a bottom surface;
a patterned metal layer disposed on the top surface of the carrier substrate and exposed out of the carrier substrate;
a CMOS image sensor dice having an active surface, a plurality of CMOS image sensor elements and a plurality of pads; the CMOS image sensor elements are disposed on the active surface, the pads are disposed around the active surface and electrically connected to a portion of the patterned metal layers;
a plurality of connecting elements disposed on a portion of the patterned metal layer and formed electrical connection;
a molding material covering the top surface of the carrier substrate, the connecting elements and the CMOS image sensor dice; and
a plurality of conductive elements formed on the connecting elements.

2. The package structure of claim 1, wherein the carrier substrate is a glass.

3. The package structure of claim 1, wherein the pads and the patterned metal layer are electrically connected by conductive glue.

4. The package structure of claim 1, wherein the connecting elements are golden fingers.

5. The package structure of claim 1, wherein the connecting elements are conductive materials.

6. The package structure of claim 1, wherein the connecting elements and the patterning metal layer are electrically connected by conductive glue.

7. The package structure of claim 1, wherein the molding material is an epoxy.

8. The package structure of claim 1, wherein the molding material is a colloid.

9. The package structure of claim 1, wherein the conductive elements are solder balls.

10. The package structure of claim 1, wherein the conductive elements are solder bumps.

11. An image catching device formed by a packaged CMOS image sensor device electrically connected to a flexible circuit board, wherein the CMOS image sensor device is characterized by:
a carrier substrate having a top surface and a bottom surface;
a patterned metal layer disposed on the top surface of the carrier substrate and exposed out of the carrier substrate;
a CMOS image sensor dice including an active surface, a plurality of CMOS image sensor elements and a plurality of pads; the CMOS image sensor elements are disposed on the active surface, the pads are disposed around the active pads and electrically connected to a portion of the patterned metal layers;
a plurality of connecting elements disposed on a portion of the patterned metal layer and formed electrical connection;
a molding material covering the top surface of the carrier substrate, the connecting elements and the CMOS image sensor dice; and
a plurality of conductive elements formed on the connecting elements.

12. The image catching device of claim 11, wherein the carrier substrate is a glass.

13. The image catching device of claim 11, wherein the connecting elements are golden fingers.

14. The image catching device of claim 11, wherein the conductive elements are solder balls.

15. The image catching device of claim 11, wherein the conductive elements are solder bumps.

16. A digital device with a CMOS image sensor device, wherein the digital device is selected from the group consisting of digital camera, mobile phone and personal digital assistant (PDA) and is characterized by:
a carrier substrate having a top surface and a bottom surface;
a patterning metal layer disposed on the top surface of the carrier substrate and exposed out of the carrier substrate;
a CMOS image sensor dice including an active surface, a plurality of CMOS image sensor elements and a plurality of pads; the CMOS image sensor elements are disposed on the active surface, the pads are disposed around the active surface and electrically connected to a portion of the patterned metal layers;
a plurality of connecting elements disposed on a portion of the patterned metal layer and formed electrical connection;
a molding material coning the top surface of the carrier substrate, the connecting elements and the CMOS image sensor dice; and
a plurality of conductive elements formed on the connecting elements.

17. The digital device of claim 16, wherein the carrier substrate is a glass.

18. The digital device of claim 16, wherein the connecting elements are golden fingers.

19. The digital device of claim 16, wherein the conductive elements are solder balls.

20. The digital device of claim 16, wherein the conductive elements are solder bumps.
